(19) United States
(12) Patent Application Publication
(10) Pub. No.: US 2017/0347488 A1
(43) Pub. Date: Nov. 30, 2017

(54) HEAT DISSIPATING DEVICE

(71) Applicant: AURAS Technology Co., Ltd., New Taipei City (TW)

(72) Inventors: An-Chih Wu, New Taipei City (TW); Che-Chia Chang, New Taipei City (TW)

(21) Appl. No.: 15/210,093

(22) Filed: Jul. 14, 2016

(30) Foreign Application Priority Data
May 27, 2016 (TW) 105116770

(51) Int. Cl. H05K 7/20

(52) U.S. Cl. CPC H05K 7/20336; H05K 7/20136; H05K 7/2039

(57) ABSTRACT

A heat dissipating device with stacked heat pipes is provided. Two layers of flat-type heat pipes are employed. A thermal pad and a fin group include convex structures and concave structures. The shapes of the convex structures and concave structures are complementary to the flat-type heat pipes. Consequently, the heat dissipating efficiency of the heat dissipating device is enhanced.

### FIELD OF THE INVENTION

The present invention relates to a heat dissipating device, and more particularly to a heat dissipating device with stacked heat pipes.

### BACKGROUND OF THE INVENTION

A heat pipe is one of the common heat dissipating devices. The heat pipe uses a capillary action to vaporize and condense liquid. During the circulation of the liquid, the temperature is cooled down. As the operating speed and performance of a central processing unit are gradually increased, the heat pipes in a single-row arrangement cannot withstand the heavy loading. For solving these problems, a stacked heat pipe structure has been developed. The stacked heat pipe structure is expected to provide the highest heat dissipating efficiency at the smallest volume. For example, a double-layer heat pipe structure disclosed in Chinese patent CN203217462 is a design of the stacked heat pipes. In the double-layer heat pipe structure, two layers of circular heat pipes are stacked on each other. Since the heat pipes are clamped between two thermal pads, some drawbacks occur. For example, the heat cannot be directly transferred from the first-layer heat pipe structure to the second-layer heat pipe structure, and the heat cannot be directly transferred from the second-layer heat pipe structure to the fins of the heat sink.

Therefore, the conventional stacked heat pipe structure needs to be further improved.

### SUMMARY OF THE INVENTION

For solving the drawbacks of the conventional stacked heat pipe structure, the present invention provides an improved stacked heat pipe structure. In accordance with the present invention, two layers of flat-type heat pipes are employed and one thermal pad is omitted. The second-layer heat pipe structure is directly contacted with fins. Since the components of the heat dissipating device are simplified and the contact area between the heat pipes is increased, the heat dissipating efficiency is enhanced. The flat-type heat pipe has an even part in a middle region thereof. Moreover, because of the plastic molding, rounded corner parts are formed at two ends of the flat-type pipe. For matching the structure of the flat-type heat pipe, the shapes of the fins are modified. For example, the fin group facing the heat pipes has a recess, and the recess has convex structures that are complementary to the rounded corner parts. Since the flatness of the heat pipes is improved, the heat generated by the chip that is in contact with the thermal pad can be quickly transferred to the first-layer heat pipe structure, the second-layer heat pipe structure and the fins. Under this circumstance, the heat dissipating efficiency is enhanced.

In accordance with an aspect of the present invention, there is provided a heat dissipating device. The heat dissipating device is attached on a chip. The heat dissipating device includes a thermal pad, plural first flat-type heat pipes, plural second flat-type heat pipes, and a first fin group. The thermal pad includes a first bottom surface and a first top surface opposed to the first bottom surface. The first bottom surface is in contact with the chip. The first top surface has plural first concave structures and plural first convex structures. Each of the plural first flat-type heat pipes includes a first even part and first rounded corner parts. Each of the plural second flat-type heat pipes includes a second even part and second rounded corner parts. The first fin group includes a recess corresponding to the plural second flat-type heat pipes. The recess has plural second concave structures and plural second convex structures. The plural first flat-type heat pipes are clamped between the plural second flat-type heat pipes and the thermal pad, top sides of the first even parts are in contact with the corresponding second even parts, bottom sides of the first even parts are in contact with the corresponding first concave structures, and the first rounded corner parts are in contact with the corresponding first convex structures. The plural second flat-type heat pipes are clamped between the first fin group and the first flat-type heat pipes, top sides of the second even parts are in contact with the corresponding second concave structures, bottom sides of the second even parts are in contact with the corresponding first even parts, and the second rounded corner parts are in contact with the corresponding second convex structures.

In an embodiment, the second flat-type heat pipes are U-type pipes, and disposed within the first fin group.

In an embodiment, a cross-section area of the first flat-type heat pipe is larger than or equal to a cross-section area of the second flat-type heat pipe.

In an embodiment, a number of the first flat-type heat pipes is larger than or equal to a number of the second flat-type heat pipes.

In an embodiment, a height of the first flat-type heat pipe is larger than or equal to a height of the second flat-type heat pipe.

In an embodiment, the heat dissipating device further includes a fan, and the fan is located at an outer side of the first fin group.

In an embodiment, the heat dissipating device further includes a second fin group, and the first flat-type heat pipes are extended from the first fin group to the second fin group.

In an embodiment, the heat dissipating device further includes a fan, and the fan is located at an outer side of the second fin group.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic perspective view illustrating a heat dissipating device according to an embodiment of the present invention;

FIG. 2A is a schematic cross-sectional view illustrating the heat dissipating device of FIG. 1 and taken along a line 2A-2A;

FIG. 2B schematically illustrates the relationships between a thermal pad, plural first flat-type heat pipes, plural second flat-type heat pipes and a first fin group of the heat dissipating device according to the embodiment of the present invention; and

FIG. 3 is a schematic perspective view illustrating the heat dissipating device according to the embodiment of the present invention and taken along another viewpoint.

### DETAILED DESCRIPTION OF THE PREFERRED EMBODIMENT

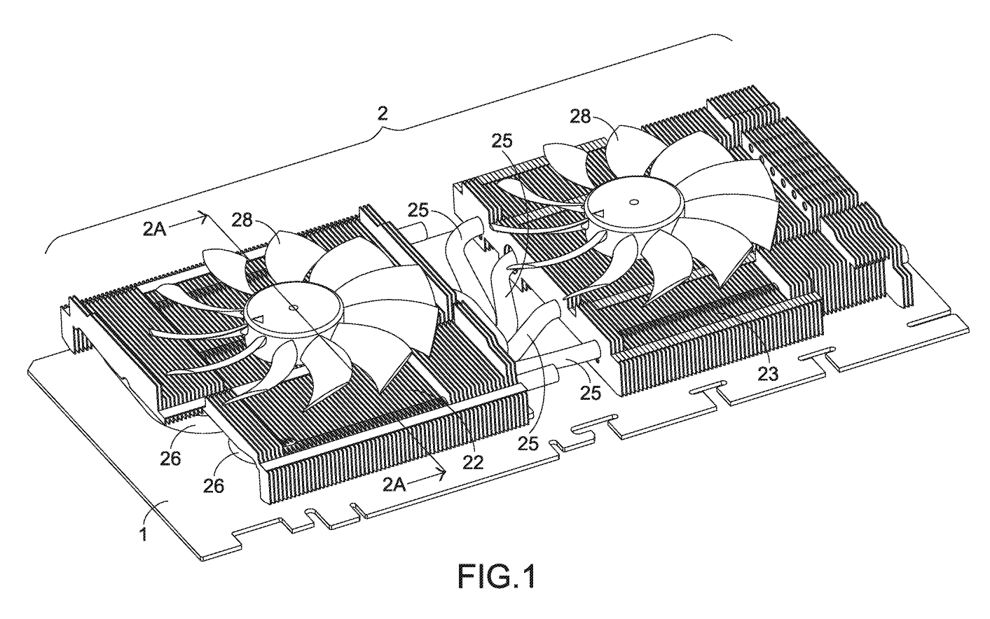

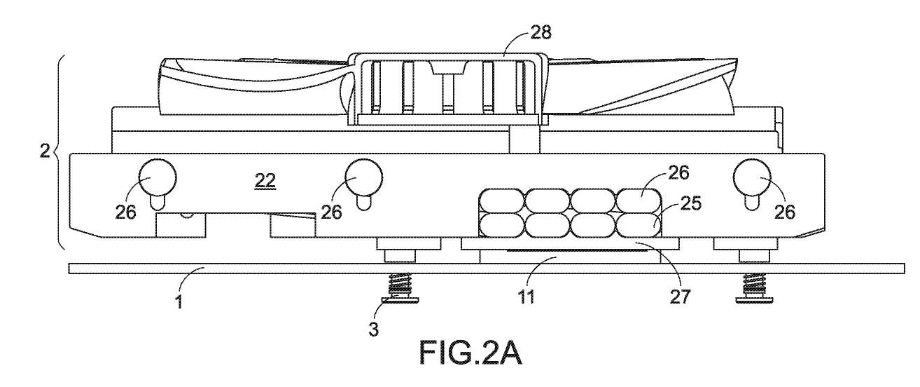

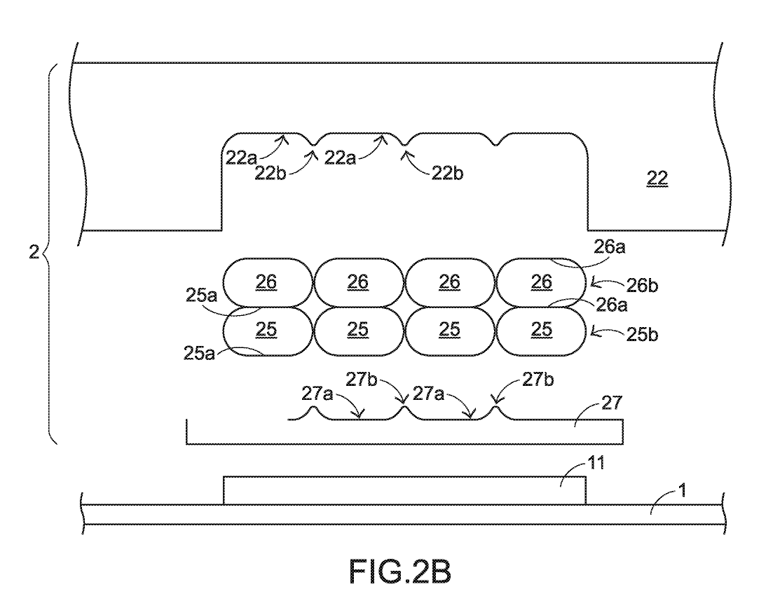

Please refer to FIGS. 1, 2A and 2B. The present invention provides a heat dissipating device 2. In this embodiment, the heat dissipating device 2 is applied to a display card 1. Alternatively, the heat dissipating device 2 is applied to any other appropriate interface card. After the heat dissipating device 2 is combined with the display card 1 through screws 3 or any other fixing means, a thermal pad 27 is attached on a chip 11. Consequently, during operation of the chip 11, the generated heat is transferred to the heat dissipating device 2 so as to be dissipated away.

The heat dissipating device 2 comprises the thermal pad 27, plural first flat-type heat pipes 25, plural second flat-type heat pipes 26, a first fin group 22, a second fin group 23 and two fans 28. The plural first flat-type heat pipes 25 and the plural second flat-type heat pipes 26 are arranged in a two-layer stack in the space between the first fin group 22 and the thermal pad 27. The fans 28 are located at an outer side of the first fin group 22 and an outer side of the second fin group 23. Moreover, each fan 28 is covered by an outer shell (not shown). The detailed structures of the components of the heat dissipating device 2 will be described as follows.

The thermal pad 27 comprises a first bottom surface and a first top surface, which are opposed to each other. The first bottom surface is in contact with the chip 11. The first top surface has plural first concave structures 27a and plural first convex structures 27b. The plural first flat-type heat pipes 25 are disposed on the thermal pad 27. Each first flat-type heat pipe 25 comprises a first even part 25a and first rounded corner parts 25b. The first even part 25a is located at a middle region of the first flat-type heat pipe 25. Moreover, the first even part 25a is produced by a laminating process or a plastic molding process. The first rounded corner parts 25b are located at two lateral sides of the first flat-type heat pipe 25. The first rounded corner parts 25b have arc-shaped surfaces. The plural second flat-type heat pipes 26 are stacked on the plural first flat-type heat pipes 25. Each second flat-type heat pipe 26 comprises a second even part 26a and second rounded corner parts 26b. The second even part 26a is located at a middle region of the second flat-type heat pipe 26. Similarly, the second even part 26a is produced by a laminating process or a plastic molding process. The second rounded corner parts 26b are located at two lateral sides of the second flat-type heat pipe 26. The second rounded corner parts 26b have arc-shaped surfaces. The first fin group 22 comprises a recess corresponding to the second flat-type heat pipes 26. Moreover, the recess has plural second concave structures 22a and plural second convex structures 22b.

Please refer to FIGS. 2A and 2B. A process of assembling the heat dissipating device will be described as follows. Firstly, the plural first flat-type heat pipes 25 and the plural second flat-type heat pipes 26 in the stack arrangement are clamped between the thermal pad 27 and the first fin group 22. That is, the plural first flat-type heat pipes 25 are clamped between the plural second flat-type heat pipes 26 and the thermal pad 27. Especially, the top sides of the first even parts 25a of the first flat-type heat pipes 25 are in contact with the corresponding second even parts 26a of the second flat-type heat pipes 26, and the bottom sides of the first even parts 25a of the first flat-type heat pipes 25 are in contact with the corresponding first concave structures 27a of the thermal pad 27. Moreover, the first rounded corner parts 25b of the plural first flat-type heat pipes 25 are in contact with the corresponding first convex structures 27b of the thermal pad 27. Moreover, the plural second flat-type heat pipes 26 are clamped between the first fin group 22 and the first flat-type heat pipes 25. Especially, the top sides of the second even parts 26a of the second flat-type heat pipes 26 are in contact with the corresponding second concave structures 22a of the first fin group 22, and the bottom sides of the second even parts 26a of the second flat-type heat pipes 26 are in contact with the corresponding first even parts 25a of the first flat-type heat pipes 25. Moreover, the second rounded corner parts 26b of the second flat-type heat pipes 26 are in contact with the corresponding second convex structures 22b of the first fin group 22.

In the above embodiment, the thermal pad 27, the first flat-type heat pipes 25, the second flat-type heat pipes 26 and the first fin group 22 are structurally aligned with and contacted with each other. Consequently, the heat generated by the chip 11 is quickly and directly transferred from the first concave structures 27a of the thermal pad 27 to the second concave structures 22a of the first fin group 22 through the first even parts 25a of the first flat-type heat pipes 25 and the second even parts 26a of the second flat-type heat pipes 26 sequentially. Under this circumstance, the heat dissipating efficiency is enhanced, and the components of the heat dissipating device are simplified. In this embodiment, the first convex structures 27b of the thermal pad 27 and the corresponding first rounded corner parts 25b of the first flat-type heat pipes 25 have complementary shapes, and the second convex structures 22b of the first fin group 22 and the corresponding second rounded corner parts 26b of the second flat-type heat pipes 26 have complementary shapes. Since the contact areas between these structures are increased, the heat dissipating efficiency of the heat dissipating device 2 is further enhanced.

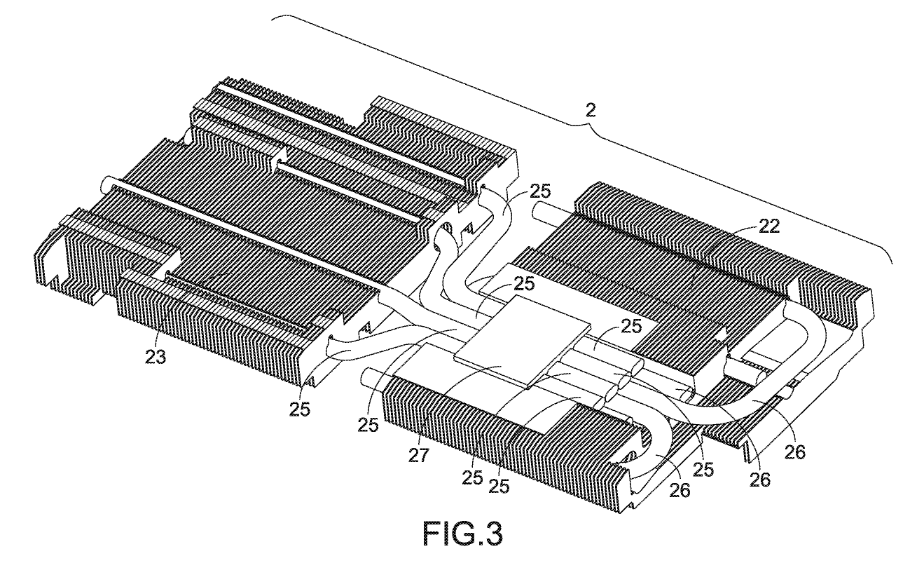

FIG. 3 is a schematic perspective view illustrating the heat dissipating device according to the embodiment of the present invention and taken along another viewpoint. As shown in FIG. 3, the plural first flat-type heat pipes 25 in contact with the thermal pad 27 are collaboratively defined as the first-layer heat pipe structure that is directly contacted with the thermal pad 27. Consequently, the first-layer heat pipe structure undertakes a greater portion of the heat dissipating task. For increasing the heat dissipating efficiency of the first-layer heat pipe structure, it is preferable to reduce the curved portions of the first flat-type heat pipes 25. Consequently, during the plastic molding process, the possibility of breaking the capillary structures inside the first flat-type heat pipes 25 will be minimized. For example, the first flat-type heat pipes 25 are extended from the first fin group 22 to the second fin group 23 to dissipate away the heat. Moreover, due to the limitation of the overall volume of the heat dissipating device 2, the second flat-type heat pipes 26 are U-shaped pipes. Because of the U-shaped pipes, the curving degree of the second flat-type heat pipe 26 is larger than that of the first flat-type heat pipe 25.

As mentioned above, the plural first flat-type heat pipes 25 undertake a greater portion of the heat dissipating task. For increasing the heat dissipating efficiency, the following approaches can be adopted. For example, the number of the first flat-type heat pipes 25 is larger than or equal to the number of the second flat-type heat pipes 26, the cross-section area of the first flat-type heat pipe 25 is larger than or equal to the cross-section area of the second flat-type heat pipe 26, or the height of the first flat-type heat pipe 25 is larger than or equal to the height of the second flat-type heat pipe 26.

As mentioned above, the heat dissipating device 2 comprises the plural first flat-type heat pipes 25 and the plural second flat-type heat pipes 26. In this context, the term “flat-type heat pipe” indicates that the width of the heat pipe is larger than the height of the heat pipe. Moreover, as long as the portions of the plural first flat-type heat pipes 25 and the plural second flat-type heat pipes 26 clamped between the thermal pad 27 and the first fin group 22 have the flat-type configurations, the purposes of the present invention can be achieved. Except for the stacked portions of the plural first flat-type heat pipes 25 and the plural second flat-type heat pipes 26, the plural first flat-type heat pipes 25 and the plural second flat-type heat pipes 26 can have the ordinary shapes such as the circular shapes or the oval shapes. That is, a part or an entire of the heat pipe having the flat shape is suitably used in the heat dissipating device of the present invention.

Moreover, the first fin group 22 and the second fin group 23 are not completely independent of each other. Since the first fin group 22 and the second fin group 23 cooperate with different fans 28, the first fin group 22 and the second fin group 23 are separated from each other. In some other embodiments, the first fin group 22 and the second fin group 23 are combined together through other fins or other components.

In some other embodiments, the gaps between the first flat-type heat pipes 25 and the second flat-type heat pipes 26 are filled with thermally-conductive medium (not shown). The thermally-conductive medium can facilitate heat transfer.

1. A heat dissipating device attached on a chip, the heat dissipating device comprising:
a thermal pad comprising a first bottom surface and a first top surface opposed to the first bottom surface, wherein the first bottom surface is in contact with the chip, and the first top surface has plural first concave structures and plural first convex structures;
plural first flat-type heat pipes, wherein each of the plural first flat-type heat pipes comprises a first even part and first rounded corner parts;
plural second flat-type heat pipes, wherein each of the plural second flat-type heat pipes comprises a second even part and second rounded corner parts; and
a first fin group comprising a recess corresponding to the plural second flat-type heat pipes, wherein the recess has plural second concave structures and plural second convex structures,
wherein the plural first flat-type heat pipes are clamped between the plural second flat-type heat pipes and the thermal pad, top sides of the first even parts are in contact with the corresponding second even parts, bottom sides of the first even parts are in contact with the corresponding first concave structures, and the first rounded corner parts are in contact with the corresponding first convex structures, wherein the plural second flat-type heat pipes are clamped between the first fin group and the first flat-type heat pipes, top sides of the second even parts are in contact with the corresponding second concave structures, bottom sides of the second even parts are in contact with the corresponding first even parts, and the second rounded corner parts are in contact with the corresponding second convex structures.

2. The heat dissipating device according to claim 1, wherein the second flat-type heat pipes are U-type pipes, and disposed within the first fin group.

3. The heat dissipating device according to claim 1, wherein a cross-section area of the first flat-type heat pipe is larger than or equal to a cross-section area of the second flat-type heat pipe.

4. The heat dissipating device according to claim 1, wherein a number of the first flat-type heat pipes is equal to a number of the second flat-type heat pipes.

5. The heat dissipating device according to claim 1, wherein a height of the first flat-type heat pipe is larger than a height of the second flat-type heat pipe.

6. The heat dissipating device according to claim 1, wherein the heat dissipating device further comprises a fan, and the fan is located at an outer side of the first fin group.

7. The heat dissipating device according to claim 1, wherein the heat dissipating device further comprises a second fin group, and the first flat-type heat pipes are extended from the first fin group to the second fin group.

8. The heat dissipating device according to claim 7, wherein the heat dissipating device further comprises a fan, and the fan is located at an outer side of the second fin group.
